(19) United States
(12) Patent Application Publication
(10) Pub. No.: US 2024/0356168 A1
(43) Pub. Date: Oct. 24, 2024

(54) ELECTRICAL INTERCONNECT BOARD FOR A BATTERY MODULE WITH INTEGRATED TEMPERATURE MEASUREMENT CAPABILITIES

(71) Applicant: Airbus SAS, BLAGNAC (FR)

(72) Inventors: Alois FRIEDBERGER, BLAGNAC (FR); Lars KÜHN, BLAGNAC (FR); Stephan FRIEDL, BLAGNAC (FR)

(21) Appl. No.: 18/637,754

(22) Filed: Apr. 17, 2024

(30) Foreign Application Priority Data
Apr. 20, 2023 (EP) 23168911.8

(51) Int. Cl. H01M 50/519; H01M 10/48; H01M 50/284; H05K 1/11; H05K 1/18

(52) U.S. Cl. CPC H01M 50/519; H01M 10/482; H01M 10/486; H01M 50/284; H05K 1/115; H05K 1/181; H05K 2201/032; H05K 2201/0352; H05K 2201/10037; H05K 2201/10151

(57) ABSTRACT

An electrical interconnect board comprises a printed circuit board and a readout device. The circuit board comprises an insulating layer, and first and second electrically conductive layers. The first and second electrically conductive layers are arranged on opposite sides of the insulating layer. The circuit board comprises receptacles each configured for accommodating a battery cell of the battery module. The first electrically conductive layer electrically interconnects the battery cells with each other. The first and second electrically conductive layers are made from different electrically conductive materials. The first and second electrically conductive layers are connected through the insulating layer at a plurality of locations by a plurality of vertical interconnect accesses (VIAs). Each VIA generates a voltage depending on the temperature at a thermoelectric interface. The readout device senses the generated voltages of the VIAs and determines corresponding temperature values.

### CROSS-REFERENCES TO RELATED APPLICATIONS

This application claims the benefit of European Patent Application Number 23168911.8 filed on Apr. 20, 2023, the entire disclosure of which is incorporated herein by way of reference.

### FIELD OF THE INVENTION

The present disclosure relates to an electrical interconnect board for a battery module. In particular, the disclosure relates to an electrical interconnect board having integrated temperature measurement capabilities for single battery cells of a battery module and to a battery module including such an electrical interconnect board.

### BACKGROUND OF THE INVENTION

Temperature generally has one of the highest impacts on electronics lifetime. Further, battery modules are manufactured from a plurality of battery cells that are usually interconnected with each other in a combined serial and parallel connection matrix. In particular in case of thermal runaway conditions of single battery cells, early detection of such conditions is important to be able to take counter measures in order to avoid damaging the battery module and the electronics of it.

For such temperature measurements, usually dedicated temperature sensors are used that either need to be wired (e.g., by means of cables) or, e.g., in PCB (printed circuit board) applications, such sensors (or rather parts of such sensor systems) need to be soldered on the PCB. To enable early detection of overheating conditions such as thermal runaway condition, ideally temperature measurements of each individual battery cell is to be implemented. This, however, is particularly challenging because of the considerable wiring effort. This wiring effort and the huge amount of connection points are a root cause for measurement faults and the reliability and the mean time between failure of the measurement system is impacted by such implementations.

Further, in case of wired sensors inside power electronics applications or batteries, the insulation coordination is impacted by the wires, and if the wires are distributed across the system, problems with regard to arc tracing may occur. This is the case in state-of-the-art battery systems. Additionally, soldering or wiring of dedicated sensors has an impact on production cost, because sensors must be produced or procured and there are additional steps necessary in the set-up of the connections. Also, in particular in aircraft applications, weight reduction generally is one of the main constraints in designing any system for the aircraft. Because of these reasons, in case of battery systems, usually just some sensors (e.g., 50 sensors) are used, and individual cell temperature monitoring (requiring usually, e.g., up to 2000 sensors or more) is not possible.

### SUMMARY OF THE INVENTION

It is an objective to provide an electrical interconnect board for a battery module having integrated individual temperature measurement capabilities for individual battery cells.

This objective may be solved by the subject matter of the one or more embodiments of the present invention described herein.

According to a first aspect, an electrical interconnect board with integrated cell temperature measurement for a battery module having a plurality of battery cells is provided. The electrical interconnect board comprises a printed circuit board and a readout device. The printed circuit board comprises an insulating layer, a first electrically conductive layer, and a second electrically conductive layer. The first electrically conductive layer and the second electrically conductive layer are arranged on opposite sides of the insulating layer. The printed circuit board comprises a plurality of receptacles each configured for accommodating a corresponding battery cell of the battery module. The first electrically conductive layer is configured to electrically interconnect the plurality of battery cells with each other. The first electrically conductive layer and the second electrically conductive layer are made from different electrically conductive materials. The first electrically conductive layer and the second electrically conductive layer are connected with each other through the insulating layer at a plurality of locations by a plurality of vertical interconnect accesses (VIAs). Each VIA builds a thermoelectric interface and thereby forms an integrated thermal sensor element that generates a voltage depending on the temperature at the thermoelectric interface. The readout device senses the generated voltages of the VIAs and determines corresponding temperature values.

In general, a printed circuit board (PCB; also printed wiring board or PWB) is a medium used in electrical and electronic engineering to connect electronic components to one another in a controlled manner. It takes the form of a laminated sandwich structure of conductive and insulating layers. Each of the conductive layers is designed with an artwork pattern of conductive tracks (or traces), planes and other features (similar to wires on a flat surface), e.g., etched from one or more sheet layers of an electrically conductive material (oftentimes copper) laminated onto and/or between sheet layers of a non-conductive substrate. Electrical components may be fixed to conductive pads on the outer layers in the shape designed to accept the component's terminals, generally by means of soldering, to both electrically connect and mechanically fasten them to it.

Such PCBs may, however, also be used to interconnect individual battery cells of a battery module with each other. According to the disclosure, for this purpose the PCB has a plurality of receptacles which are designed to accommodate the individual battery cells and connect them with each other in a predefined electrical circuit, e.g., in a matrix of serial and parallel connections. For the interconnection of the individual cells, the first electrically conductive layer may be structured/designed to achieve the desired interconnection pattern of the individual battery cells and in particular has corresponding connection points, such as the contact elements described further below, that are configured to contact the electrodes of the battery cells. For example, receptacles for battery cells that are arranged in a line in one of the extension directions of the PCB may be interconnected with each other in a serial connection, while each of such line may be interconnected in a parallel connection. However, any other connection scheme is possible, too.

The receptacles may, e.g., be corresponding cut-outs or recesses in the insulating layer sized to accommodate the individual battery cells, while the first electrically conductive layer is shaped to interconnect these battery cells with each other, when they are placed in the receptacles. The first electrically conductive layer may, e.g., be a non-uniform layer, such as in a regular PCB, where the conductive tracks are routed to each of the receptacles to provide corresponding connection points, i.e., terminals, for the battery cells.

To provide integrated temperature measurement capabilities, the PCB further comprises the second electrically conductive layer. The second conductive layer in general is separated from the first conductive layer by the insulating layer.

The disclosed electrical interconnect board utilizes the thermoelectric effect (“Seebeck effect”, also sometimes referred to as the “Peltier-Seebeck effect”) to provide temperature measurement at certain positions/locations of the electrical interconnect board (in particular near the locations of the receptacles and therefore near the locations of individual battery cells, when the battery cells are connected by the electrical interconnect board).

In general, thermoelectricity is the relationship between temperature gradient and electrical voltage along an electrical conductor. This relationship is different for each conductor material. In an open circuit consisting of two different conductor materials, there is a difference between these internal voltages, which is accessible externally at the free ends as a thermoelectric voltage. In a closed circuit, the thermoelectric voltage generates an electric current and thus directly electrical energy, which is taken from the thermal energy in the junction points between the materials. The relationship between the temperature and voltage is described by so called Seebeck coefficients of the materials involved. These Seebeck coefficients are material constants of the respective materials. If the Seebeck coefficients of the involved materials are different, the Seebeck effect, as described above, occurs.

Therefore, the first electrically conductive layer and the second electrically conductive layer are made from different electrically conductive materials (in particular materials having different Seebeck coefficients) and are connected with each other through so called vertical interconnect accesses (VIAs). In other words: the VIAs provide through plating junctions between the first electrically conductive layer and the second electrically conductive layer. That is, the first electrically conductive layer and the second electrically conductive layer comprise corresponding conductive tracks which are connected with each other through the VIAs. The respective conductive tracks on the other hand are connected to the readout device. Since the first electrically conductive layer and the second electrically conductive layer (i.e., the conductive tracks of these layers) are made from different (electrically conductive) materials, these junctions can be used as an integrated temperature sensor (thermocouple or thermoelement) by analyzing the difference of the electrical potentials of the corresponding tracks of the first electrically conductive layer and of the second electrically conductive layer (i.e., the thermoelectrically created voltage). For this, the readout device is configured to measure the voltage and to determine a temperature value corresponding to the measured voltage based on the known Seebeck coefficients of the material of the first electrically conductive material and of the second electrically conductive material. In principle, such thermocouples may be located at any position on the PCB. Therefore, individual battery cell temperature monitoring of each battery cell interconnected by the electrical interconnect board can be achieved by providing a corresponding VIA near every receptacle for a battery cell. However, corresponding VIAs may also be located near only some of the receptacles.

Although described as connecting the first electrically conductive layer (which, as described further above, also acts as electrical interconnection layer for the battery cells) and the second electrically conductive layer, it should be appreciated that the PCB may also comprise a third (or even more) electrically conductive layer, that is isolated form the other electrically conductive layers, for example, by one or more additional insulating layers. The thermocouples may then also be created by interconnecting, for example, the second electrically conductive layer and the third electrically conductive layer by corresponding VIAs, such that the second electrically conductive layer and the third electrically conductive layer act purely as thermocouple layers. In such configurations, too, at least the layers participating in the thermoelectric effect (i.e., the second and third electrically conductive layers) are made from different electrically conductive materials, in particular from materials having different Seebeck coefficients, such that a temperature difference at the junctions (at the VIAs) causes a voltage drop at the corresponding conductive tracks of the layers.

Overall, the number of sensors is just limited by the size of the PCB and the sensor electronics. Therefore, high resolution temperature maps may be measured for a battery module utilizing the electrical interconnect board. Therefore, in particular, early detection of thermal runaway conditions of individual battery cells is possible. This allows shutdown the battery system/battery module before a critical cell temperature can emerge. Such conditions may, for example, occur if an individual battery cell reaches a higher temperature than others due to poor manufacturing quality, or if the cooling in the area of one or some battery cells is not functional. Variations among battery cells may also occur in heavily aged cells, which is why some battery cells may reach higher temperatures than others.

Instead of dedicated temperature sensor parts (e.g., SMD sensors, based on different technologies) which need to be soldered or wired, the disclosed thermal sensor elements (implemented by the VIAs) is built directly as part of the PCB by adding an additional conductive layer and through plating elements (VIAs).

The readout device may be any device or arrangement of devices suitable for analyzing the corresponding signals from the corresponding VIAs. The readout device may, e.g., be an arrangement of microchips on the PCB, wherein each microchip is associated with specific VIAs for analyzing their signals. However, the readout device may also be a device external to the PCB, such as a general-purpose computer having a CPU and corresponding memory components and programming for analyzing the signals. In such configurations, the conductive tracks of the first and second electrically conductive layers corresponding to the VIAs may be routed to an externally accessible terminal of the PCB which may be connected to the external computer or device. Such a terminal may also be present when using dedicated microchips to control and read out these microchips by an external device, such as a computer. In this case, corresponding conductive tracks from the microchips may be routed to the externally accessible terminal.

The disclosed electrical interconnect board offers high availability for multi sensor applications, such as individual battery cell temperature monitoring. In particular, the implementation is very cost efficient and no additional production time for the implementation is necessary. Further, the sensor principle is also applicable for laminated bus bars. In this case, however, VIAs would not necessarily have to be used as sensors, although they also could. Since in laminated bus bars, foils are laminated, an additional degree of freedom arises. Such foils can have different blanks. In laminated bus bars, tongues or tabs made of the two different materials lying on top of each other can be guided up to above the battery cells, and the welding point of both of these tongues/tabs on one electrical terminal of the battery cells forms the contact and thus also the temperature sensor in the same way as the described VIAs do. Manufacturing of the discloses electrical interconnect board is very similar to the manufacturing of regular PCBs. The disclosed sensor principle therefore not only is applicable for the disclosed electrical interconnect board but also with any PCB. For both PCBs and laminated bus bars, a standard insulation coordination process is applicable. The defined process and the utilized implementation of the connection between sensors and sensor electronics (readout device) is much safer than the implementation of wired sensors. Also, since dedicated temperature sensors (e.g., sensor elements soldered onto the PCB) are avoided, weight of the overall battery module can be greatly reduced. Because of the enhanced safety, reliability, cost-efficiency, and the reduced weight, the disclosed electrical interconnect board enables an individual battery cell temperature monitoring for battery modules.

According to an embodiment, the plurality of receptacles are corresponding recesses in the printed circuit board. The first electrically conductive layer protrudes into each of the plurality of recesses, thereby building contact elements configured to contact electrodes of a corresponding one of the battery cells, such that the battery cells of the battery module are electrically connected to each other to build an electrical circuit of battery cells.

Such recesses may, for example, be corresponding cut-outs in the PCB, especially in the insulating layer. The first electrically conductive layer may then protrude into these recesses, for example, in the form of contact tabs or other contact elements (i.e., terminals) which are part of a first electrically conductive layer. These contact elements may be interconnected with each other by corresponding conductive tracks of the first electrically conductive layer, such that the desired circuitry between the contact elements (i.e., between the battery cells, when the electrical interconnect board is in use) is established. In particular, two such contact elements may be present for each recess, such that a positive and a negative terminal for the corresponding battery cell is provided.

The recesses and the contact elements are formed accordingly to support and connect the desired design battery cell type. If the design battery cell type is a cylindrical cell, the recess may be cylindrical, if the design battery cell type is a rectangular cell, the recess may be rectangular, and so on. The contact elements protrude into these recesses, such that they can contact the terminals of the corresponding battery cell type. The battery cells may be constructed such that both the positive and the negative terminals, are accessible from one side of the battery cell. For example, in cylindrical battery cells, the negative terminal (which usually is arranged opposite the positive terminal) may be electrically connected to the cylindrical housing of the battery cell, such that the negative terminal may be contacted at an edge of the side of the battery cell where the positive terminal is located. In this way, both terminals of a battery cell may be contacted by the contact elements of the electrical interconnect board from the same side of the battery cell. The desired circuitry may then be achieved by appropriately designing the conductive tracks of the first electrically conductive layer.

According to another embodiment, the first electrically conductive layer is made from copper.

Copper is a common material for PCBs comprising excellent electrical conductivity.

According to another embodiment, the second electrically conductive layer is made from a copper-nickel alloy.

Such a copper-nickel alloy can be easily joined to the copper material of the first electrically conductive material and, in combination with copper, exhibits the Seebeck effect described above.

According to another embodiment, the second electrically conductive layer is made from constantan.

Constantan is a copper-nickel alloy usually consisting of 55% copper and 45% nickel. However, other compositions are possible, too. The material of the second conductive material may, for example, comprise 50% copper and 50% nickel, 60% copper and 40% nickel, 65% copper and 35% nickel, or any other composition of copper and nickel.

Constantan together with copper builds a standardized thermal element/thermocouple which is referenced as a T type thermocouple. The physical properties of such a thermocouple are well understood. Since constantan is copper based, a constantan layer can be processed in the same way as a copper layer to build conductive tracks to connect the thermal sensor elements (formed by the VIAs) with the readout device. Therefore, VIAs between a copper layer and a constantan layer can be produced in a common production process for PCB. Therefore, a combination of a copper layer as the first electrically conductive layer and a constantan layer as the second electrically conductive layer is preferred because it allows for a relatively simple production process.

According to another embodiment, the location of each VIA is located near a corresponding contact element of an associated recess, such that the thermal sensor element formed by the corresponding VIA measures a temperature near the location of the corresponding contact element.

By arranging each VIA near a corresponding contact element, the thermal sensor element formed by the VIA measures the temperature in the direct neighborhood of the corresponding battery cell and gives an indication of the temperature of the battery cell itself.

According to another embodiment, the corresponding contact element is configured to conduct heat from an associated battery cell to the corresponding VIA, such that the thermal sensor element formed by the corresponding VIA indicates a temperature of the associated battery cell.

The contact elements are in direct contact with the terminals of the battery cells when connected by the electrical interconnect board. Since the contact elements are made from an electrically conductive material, they also provide at least some thermal conductivity. Therefore, heat from the battery cells, such as when one of the battery cells exhibits a thermal runaway condition, is conducted from the battery cell to the corresponding VIA. Since heat from the battery cell is conducted to the VIA, the temperature measured by the thermoelectric effect at the VIA substantially corresponds to the temperature of the battery cell itself. Preferably, the material of the first electrically conductive layer comprises large heat transfer capabilities.

According to another embodiment, the contact elements of each recess comprise a positive contact element configured to contact a positive electrode of the battery cell and a negative contact element configured to contact a negative electrode of the battery cell.

According to another embodiment, at least one of the positive contact element and the negative contact element is split into a connection section and a sensor section.

Since the contact elements within each recesses act as terminal elements for battery cells, the contact elements conduct electrical current. Because of the electrical resistance of the contact elements, the current flow through the contact elements therefore leads to an increase in temperature of the contact element. The corresponding heat may be transferred to the corresponding VIAs and therefore may influence or falsify the temperature measurement results. In order to avoid this, the contact elements, which are associated with the corresponding thermal sensor elements (VIAs) may be split into two distinct parts or sections: a connection section and a sensor section. The sensor section serves only to conduct heat from the battery cells to the corresponding VIA and does not conduct any electrical current from the corresponding battery module. For this, the sensor section is connected to the corresponding VIA. The connection section is isolated from the corresponding VIA and only serves to conduct electrical current from the associated battery cell. In other words: the sensor sections conduct only heat from the battery cell to the thermal sensor element to sense the temperature of the corresponding battery cell while the connection sections electrically interconnect the individual battery cells with each other.

According to another embodiment, the sensor section and the connection section are electrically and/or thermally isolated from each other.

For this, for example the sensor section and the connection section may, for example, be isolated from each other by providing an air gap between the connection section and the sensor section. This air gap may, e.g., be provided by etching during the PCB production process or by laser cutting afterwards. Optionally, the air gap may be filled with an electrically and thermally isolating material, such as a corresponding resin or other insulating material.

According to another embodiment, the connection section is configured for electrically connecting and thereby integrating the battery cell into the electrical circuit of battery cells.

According to another embodiment, the sensor section is associated with a corresponding VIA and configured to conduct thermal energy of the battery cell to the corresponding VIA.

According to another embodiment, the readout device comprises at least one sensor chip. A conductive track of the first electrically conductive layer and a conductive track of the second electrically conductive layer that are associated with a corresponding VIA are connected to a corresponding one of the sensor chips, such that the corresponding sensor chip is configured to measure a voltage between the corresponding conductive tracks of the first electrically conductive layer and of the second electrically conductive layer and to determine a corresponding temperature value based on the measured voltage.

The sensor chips may, for example, be accordingly configured microchips which measure the voltage at each corresponding VIA and to determine an associated temperature at the corresponding VIA (as described above) and therefore at the corresponding battery cell, when the electrical interconnect board is used to interconnect the battery cells to build a battery module. Each sensor chip may also be associated to multiple VIAs or each sensor chip may be associated to a single VIA. Further, the sensor chips itself may be connected with a superordinate control device, such as a computer having a display device or any other suitable device, to allow a user to display and/or process the measured temperature values.

According to another embodiment, the electrical interconnect board further comprises at least one dedicated reference temperature sensor arranged in the vicinity of the at least one sensor chip.

Since an additional connection between the conductive tracks from the corresponding VIA to the sensor chip is necessary, a further thermocouple between different materials may exist that influences the overall measured voltage. A dedicated reference temperature sensor may therefore be present near each of the sensor chips, such that the temperature near the corresponding sensor chip may be determined by the reference temperature sensor. By using the detected temperature value from the reference temperature sensor near the sensor chip, the sensor chip may calculate the effect of the second thermocouple out of the determined temperature value.

According to a second aspect, a battery module is provided. The battery module comprises a plurality of battery cells and an electrical interconnect board of any one of the embodiments described above. Each of the plurality of battery cells is arranged within a corresponding one of the receptacles, such that the battery cells are connected with each other to form a circuit of battery cells.

The electrical interconnect board may be configured according to any one of the embodiments described herein. Therefore, each feature described with regard to the electrical interconnect board is equally applicable for the battery module.

In summary, the present disclosure provides an electrical interconnect board for a battery module and a corresponding battery module comprising such electrical interconnect board with integrated temperature measurement capabilities that do not rely on wired or soldered temperature sensors. Rather, the described electrical interconnect board comprises inherently integrated thermal sensor element in the form of VIAs in a printed circuit board. Therefore, wiring effort and connection points are greatly reduced and temperature measurement of single battery cells of a battery module can be implemented.

Although the present disclosure is described with regard to battery module applications, it should be appreciated that the disclosed measuring principle is equally applicable for any electronic component relying on temperature measurements at defined locations.

### BRIEF DESCRIPTION OF THE DRAWINGS

In the following, exemplary embodiments are described in more detail having regard to the attached figures. The illustrations are schematic and not to scale. Identical reference signs refer to identical or similar elements. The figures show:

FIG. 1 is a schematic perspective view of an electrical interconnect board with integrated single cell temperature measurement capabilities for cylindrical battery cells in a battery module;

FIG. 2 is a schematic top view and a perspective view of a receptacle of the electrical interconnect board of FIG. 1;

FIG. 3 is a schematic top view and a perspective view of a receptacle of the interconnect board of FIG. 1 having connect elements that are split in a connection section and in a sensor section;

FIG. 4 is a schematic cross-sectional view of a receptacle of an interconnect board illustrating possible lay ups of a printed circuit board of the electrical interconnect board;

FIG. 5 is a schematic top view of an interconnect board for a battery module illustrating routing and connecting of the integrated thermal sensor elements implemented by vertical interconnect accesses (VIAs) to corresponding sensor chips; and,

FIG. 6 is a schematic view of a battery module having a plurality of battery cells that are interconnected with the disclosed electrical interconnect board.

### DETAILED DESCRIPTION OF THE PREFERRED EMBODIMENTS

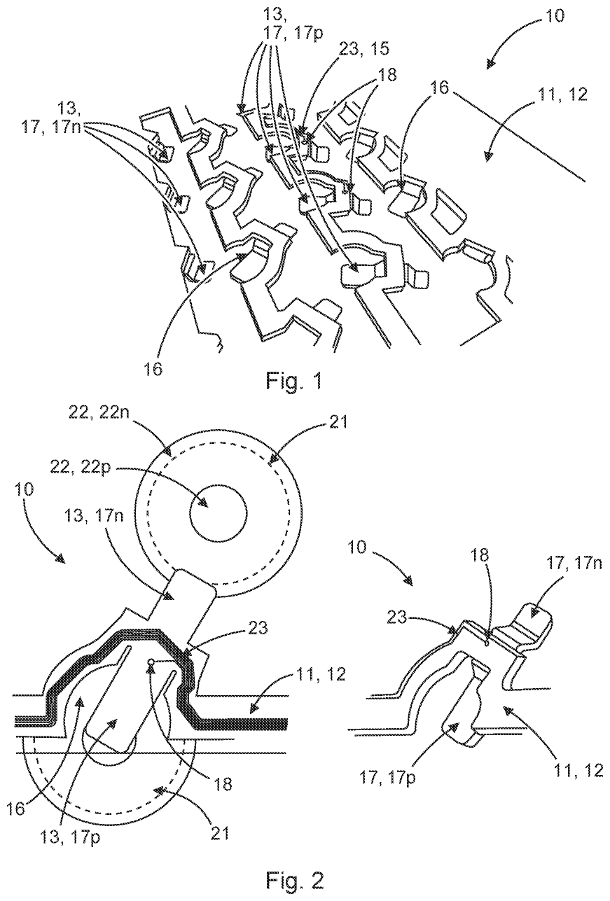

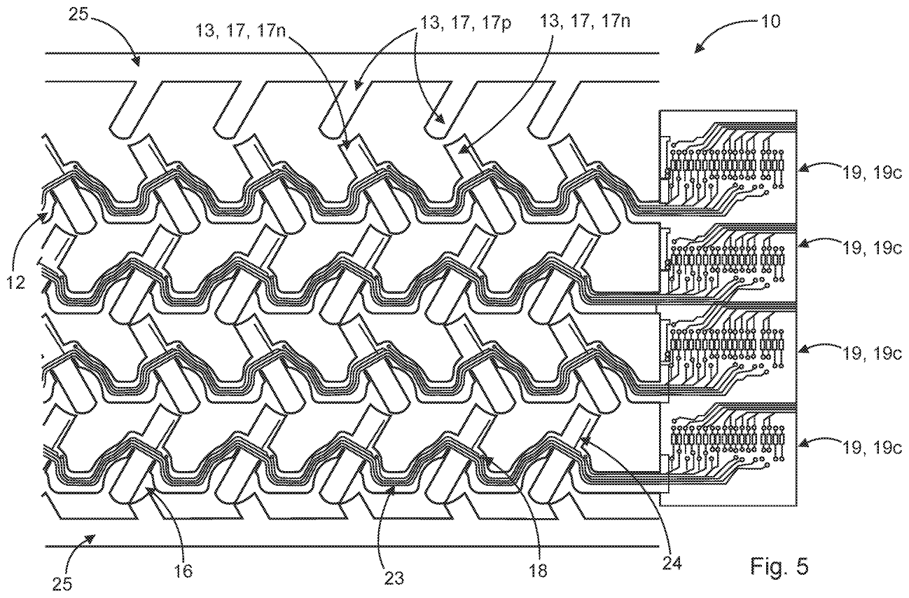

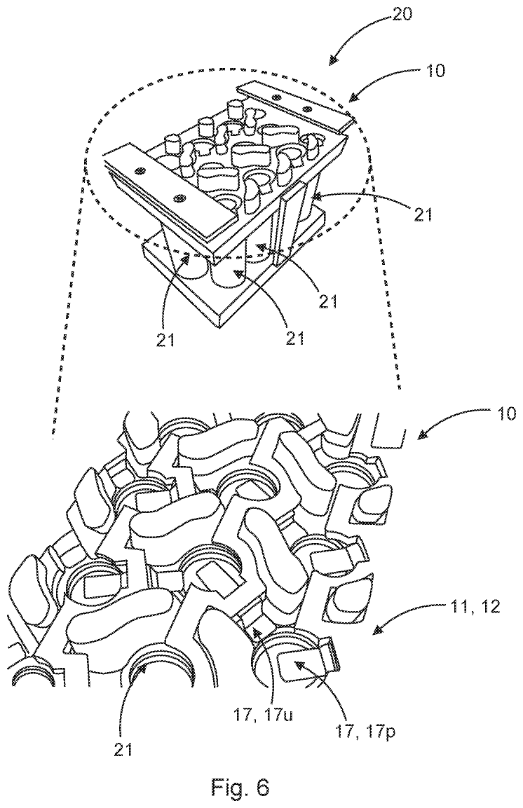

FIG. 1 schematically shows an electrical interconnect board 10 with integrated cell temperature measurement for a battery module 20 (not shown in FIG. 1, see, FIG. 6). The electrical interconnect board 10 comprises a printed circuit board (PCB) 11 having an insulating layer 12, a first electrically conductive layer 13 and a second electrically conductive layer 14 (not explicitly shown in FIG. 1, see cross section in FIG. 4). The insulating layer 12 comprises a plurality of receptacles 16 (two indicated by reference signs) in the form of recesses 16 (or cut outs) in the insulating layer that are shaped to accommodate individual battery cells 21 (see FIGS. 2 and 6). The first electrically conductive layer 13 is arranged on a bottom side of the PCB 11 and comprises a plurality of contact elements 17 for contacting electrodes 22 (see FIG. 2) of battery cells 21. The contact elements 17 are distinguished in positive contact elements 17p and negative contact elements 17n. The positive contact elements 17p are configured to contact a positive electrode 22p (FIG. 2) of a battery cell 21. The negative contact elements 22n (FIG. 2) are configured to contact a negative electrode 22n of a battery cell 21. Although shown as being configured for cylindrical battery cells 21, it should be appreciated that the receptacles/recesses 16 and the contact elements 17 may also be configured to accommodate any other kind of battery cell 21, such as pouch cells, rectangular cells, etc.

A plurality of vertical interconnect accesses (VIAs) 18 are shown in FIG. 1. Such VIAs 18 extend in a vertical direction through the PCB 11 and interconnect the first electrically conductive layer 13 with the second electrically conductive layer 14.

The first electrically conductive layer 13 and the second electrically conductive layer 14 are made from different electrically conductive materials, in particular from materials having different Seebeck coefficients, as described further above, such that a thermocouple (a junction between different materials experiencing a thermoelectric effect) is formed. For example, the first electrically conductive layer 13 may be made from copper and the second electrically conductive layer 14 may be made from a copper-nickel alloy, such as constantan. However, other suitable material combinations are possible, too. The VIAs 18, interconnecting the different materials of the first electrically conductive layer 13 and the second electrically conductive layer 14, act as such thermocouples (i.e., thermal sensor elements). The VIAs 18 (or rather at the junction of the different materials within the VIAs 18) generate a voltage depending on the temperature at the corresponding junction. This voltage is routed by means of conductive tracks 23 to at least one readout device 19 (see FIG. 5). The readout device 19 may then analyze the voltage and determine a corresponding temperature based on the known material constants of the different electrically conductive layers 13, 14.

In the shown configuration of FIG. 1, the second electrically conductive layer 14 is an inner layer of the PCB 11 and on top of the insulating layer 12, an additional electrically conductive layer 15 having conductive tracks 23 is arranged, which is connected through the VIAs 18 with the first electrically conductive layer 13 and only acts as signal routing layer to a readout device 19 (FIG. 5). However, the second electrically conductive layer 14 may also be arranged directly on the top side of the insulating layer 12. In general, any arrangement of electrically conductive layers providing an interface between electrically conductive materials having different Seebeck coefficients is possible.

FIG. 2 shows a schematic top view (on the left side) and schematic perspective view (on the right side) of one of the receptacles/recesses 16 of FIG. 1. In FIG. 2, the signal routing by means of conductive tracks 23 form the different VIAs 18 associated with the receptacles 16 is clearly visible. Further, in FIG. 2, two cylindrical battery cells 21 with electrodes 22, in particular each with a positive electrode 22p and a negative electrode 22n, are schematically illustrated. The negative electrode 22n is provided at a circumferential region of the cylindrical battery cells 21 and on the same side in the longitudinal direction of the battery cell 21 as the positive electrode 22p. For example, the negative electrode 22n (which, in cylindrical cells, is usually arranged on the opposite side in the longitudinal direction as the positive electrode 22p) can be routed to the circumferential region at the longitudinal side of the positive electrode 22p via an electrically conductive shell of the battery cell 21. In this way, the interconnection of all battery cells 21 can be achieved within the substantially plane electrical interconnect board. As can be seen, the positive contact element 17p and the negative contact element 17n of the first electrically conductive layer 13 interconnect the two battery cells 21 shown in FIG. 1 in a serial connection.

One of the plurality of VIAs 18 is shown in FIG. 2 as being arranged on the positive contact element 17p of the first electrically conductive layer 13. The VIA 18 thereby acts as thermal sensor element, as described above. The contact elements 17, in addition to the function as establishing the electrical interconnection of the individual battery cells 21 with each other, conduct heat from the battery cells 21 to the VIA 18 and therefore to the thermocouple, as described above, which is why the temperature measured at the thermocouple is indicative of the temperature of the battery cell 21.

It should be appreciated that the VIAs 18 may also be arranged on the negative contact element 17n. This may be even more advantageous, because the negative contact elements 17n directly contact the circumferential regions of the cylindrical battery cells 21, which is in direct contact with the enclosure of the battery cells 21. Therefore, especially in situations with fast temperature increases (such as in thermal runaway conditions), fast detection of the temperature increase is possible because the heat is almost immediately transferred to the thermocouple build by the VIA 18.

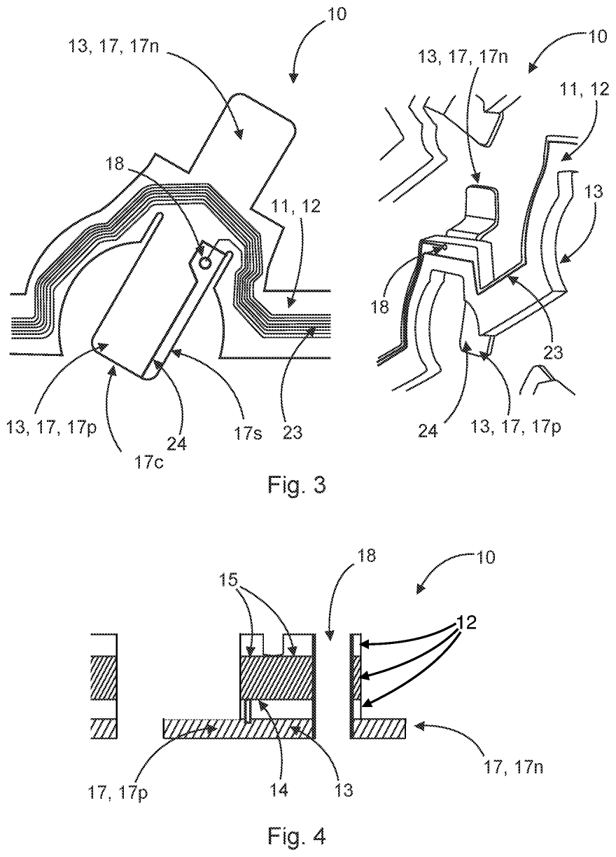

FIG. 3 shows an alternative configuration of the electrical interconnect board 10. This configuration differs from the configuration in FIG. 2 in that the contact element 17 containing the VIA 18 is split into a connection section 17c and a sensor section 17s by an air gap 24. The air gap 24 may be filled with an electrically and thermally isolating material. The air gap 24 may, for example, be achieved during the manufacturing process of the PCB 11, e.g., by etching, or afterwards, e.g., by laser cutting. However, other manufacturing methods are possible, too. The splitting into the sections 17c, 17s has the advantage that heat flux to the VIA 18 caused by the current flow between the individual battery cells 21 is avoided. Therefore, the heat transferred to the VIA 18 (i.e., the thermocouple within the VIA 18) is “real” heat from the battery cell 21 associated with the VIA 18. The temperature indicated by the thermocouple therefore more precisely reflects the temperature of the corresponding battery cell 21.

FIG. 4 shows a cross sectional view of one of the receptacles 16 of the electrical interconnect board 10 of FIGS. 1 to 3 illustrating a possible lay-up. The PCB 11 comprises a first electrically conductive layer 13, a second electrically conductive layer 14 and third and fourth electrically conductive layers 15 (n-th electrically conductive layers 15).

It should be noted that the n-th electrically conductive layers 15 are optional. A minimal lay-up would also work with just the first electrically conductive layer 13 and the second electrically conductive layer 14. In this case, corresponding conductive tracks 23 that provide the corresponding signal routings to the readout device 19, 19c (not shown in FIG. 4, see FIG. 5) would be present in each of the first and the second electrically conductive layers 13, 14.

Each of the electrically conductive layers 13, 14, 15 is isolated from each other by an insulating layer 12. A vertical interconnect access (VIA) 18 reaches through the PCB 11 and electrically interconnects each of the layers 13, 14, 15 with each other. The first electrically conductive layer 13 comprises contact elements 17, such as the positive contact element 17p and the negative contact element 17n, that reach or protrude into the receptacles or recesses 16. In particular, the positive contact element 17p and the negative contact element 17n reach into neighboring receptacles 16, such that the positive contact element 17p and the negative contact element 17n connect battery cells 21 inserted into these receptacles in a serial manner. The receptacles 16 are configured to accommodate a battery cell 21, as described above.

The first electrically conductive layer 13 and the second electrically conductive layer 14 are made from different electrically conductive materials, in particular from electrically conductive materials comprising different Seebeck coefficients. For example, the first electrically conductive layer 13 may be made from copper and the second electrically conductive layer may be made from a copper-nickel alloy, such as constantan. However, any other suitable material combination is conceivable, too. The VIA 18 may be made from the same material as the first electrically conductive layer 13. Therefore, at the junction between the second electrically conductive layer 14 and The VIA 18 (and therefore between the first and the second electrically conductive layers 13, 14), a thermocouple is built, such that the VIA 18 acts as a thermal sensor element. Therefore, a differential voltage is created between the first and the second electrically conductive layer 13, 14, which depends on a temperature at the location of the VIA 18 (or rather at the location of the junction between the layers). The second electrically conductive layer 14 and the first electrically conductive layer 13 may then be contacted and connected to corresponding readout devices 19 (i.e., for example, sensor chips 19c, as shown in FIG. 5) via corresponding conductive tracks 23, as described herein. The optional n-th electrically conductive layers 15 may, for example, act as separate signaling or readout layers for contacting at least one of the first and the second electrically conductive tracks 13, 14.

FIG. 5 shows a possible connection scheme of an electrical interconnect board 10. The lay-up of the printed circuit board (PCB) 11 and the configuration of the receptacles/recesses 16 in the PCB 11 may be configured according to any one of the embodiments described with regard to FIGS. 1 to 4 or otherwise described herein. The illustrated electrical interconnect board 10 is configured to connect a vertical line of battery cells 21 (as illustrated three battery cells each) in series. These serial connections of battery cells 21 are connected in parallel with each other by parallel connections 25, which may, for example, be busbars, which are part of the first electrically conductive layer 13. However, any other connection scheme is possible, too.

In FIG. 5, it is clearly visible, how the VIAs 18, and therefore the corresponding thermocouples, which are each associated with a specific receptacle 16 (and therefore with a specific battery cell 21, when in use) are connected with corresponding readout devices 19, such as sensor chips 19c, via corresponding conductive tracks 23, as described further above. In the illustrated example, each sensor chip 19c serves one horizontal line of receptacles 16 (or rather VIAs 18 of the receptacles 16). However, a single sensor chip 19c may also serve any other number of VIAs 18.

FIG. 6 shows a battery module 20 comprising a plurality of battery cells 21 and an electrical interconnect board 10, as described herein. The electrical interconnect board 10 may be configured according to any one of the embodiments described herein. The bottom part of FIG. 6 shows the top section of the battery module 20, and therefore the electrical interconnect board 10, enlarged. The contact elements 17 of the electrical interconnect board 10, may, for example, be laser welded to the electrodes of the battery cells 21. However, any other connection is conceivable, too.

In summary, the disclosed electrical interconnect board 10 provides the ability for single cell temperature measurement for battery modules 20 comprising a plurality of battery cells 21. The proposed solution avoids any wired or soldered sensor elements and therefore decreases weight, increases security by monitoring each cell temperature, and provides a versatile electrical interconnection. In particular, potentially dangerous situation, such as thermal runaway conditions of battery cells 21, can be detected very fast because the temperatures of each battery cell can be continuously monitored.

The systems and devices described herein may include a controller or a computing device comprising a processing and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

It should be noted that “comprising” or “including” does not exclude other elements or steps, and “one” or “a” does not exclude a plurality. It should further be noted that features or steps that have been described with reference to any of the above embodiments may also be used in combination with other features or steps of other embodiments described above. Reference signs in the claims are not to be regarded as limitation.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

### LIST OF REFERENCE SIGNS

10 electrical interconnect board
11 printed circuit board (PCB)
12 insulating layer
13 first electrically conductive layer
14 second electrically conductive layer
15 n-th electrically conductive layer
16 receptacles, recesses
17 contact elements
17c connection section (of contact element)
17s sensor section (of contact element)
17p positive contact element
17n negative contact element
18 vertical interconnect access (VIA)
19 readout device
19c sensor chip
20 battery module
21 battery cells
22 electrodes
22p positive electrode
22n negative electrode
23 conductive tracks
24 air gap, isolating material
25 parallel connections
30 reference temperature sensor

1. An electrical interconnect board with integrated cell temperature measurement for a battery module having a plurality of battery cells, the electrical interconnect board comprising:
a printed circuit board and a readout device,
wherein the printed circuit board comprises an insulating layer, a first electrically conductive layer, and a second electrically conductive layer;
wherein the first electrically conductive layer and the second electrically conductive layer are arranged on opposite sides of the insulating layer;
wherein the printed circuit board comprises a plurality of receptacles each configured for accommodating a corresponding battery cell of the battery module;
wherein the first electrically conductive layer is configured to electrically interconnect the plurality of battery cells with each other;
wherein the first electrically conductive layer and the second electrically conductive layer are made from different electrically conductive materials;
wherein the first electrically conductive layer and the second electrically conductive layer are connected with each other through the insulating layer at a plurality of locations by a plurality of vertical interconnect accesses referred to as VIAs;
wherein each VIA builds a thermoelectric interface and thereby forms an integrated thermal sensor element that generates a voltage depending on a temperature at a respective thermoelectric interface; and
wherein the readout device senses generated voltages of the VIAs and determines corresponding temperature values.

2. The electrical interconnect board of claim 1, wherein the plurality of receptacles comprises a plurality of recesses; and
wherein the first electrically conductive layer protrudes into each of the plurality of recesses, thereby building contact elements configured to contact electrodes of a corresponding one of the battery cells, such that the battery cells of the battery module are electrically connected to each other to build an electrical circuit of battery cells.

3. The electrical interconnect board of claim 1, wherein the first electrically conductive layer is made from copper.

4. The electrical interconnect board of claim 1, wherein the second electrically conductive layer is made from a copper-nickel alloy.

5. The electrical interconnect board of claim 4, wherein the second electrically conductive layer is made from constantan.

6. The electrical interconnect board of claim 2, wherein each VIA is located at a location proximate a corresponding contact element of an associated recess, such that the thermal sensor element formed by the corresponding VIA measures a temperature proximate the location of the corresponding contact element.

7. The electrical interconnect board of claim 6, wherein the corresponding contact element is configured to conduct heat from an associated battery cell to the corresponding VIA, such that the thermal sensor element formed by the corresponding VIA indicates a temperature of the associated battery cell.

8. The electrical interconnect board of claim 2, wherein the contact elements of each recess comprise a positive contact element configured to contact a positive electrode of the battery cell and a negative contact element configured to contact a negative electrode of the battery cell.

9. The electrical interconnect board of claim 8, wherein at least one of the positive contact element and the negative contact element is split into a connection section and a sensor section.

10. The electrical interconnect board of claim 9, wherein the sensor section and the connection section are electrically isolated, or thermally isolated, or electrically and thermally isolated from each other.

11. The electrical interconnect board of claim 10, wherein the connection section is configured for electrically connecting and thereby integrating the battery cell into the electrical circuit of battery cells.

12. The electrical interconnect board of claim 10, wherein the sensor section is associated with a corresponding VIA and configured to conduct thermal energy of the battery cell to the corresponding VIA.

13. The electrical interconnect board of claim 1, wherein the readout device comprises at least one sensor chip;
wherein a conductive track of the first electrically conductive layer and a conductive track of the second electrically conductive layer that are associated with a corresponding VIA are connected to the at least one sensor chip, such that the at least one sensor chip is configured to measure a voltage between the corresponding conductive tracks of the first electrically conductive layer and of the second electrically conductive layer and to determine a corresponding temperature value based on a measured voltage.

14. The electrical interconnect board of claim 13, further comprising at least one dedicated reference temperature sensor arranged proximate to the at least one sensor chip.

15. A battery module comprising:
a plurality of battery cells; and
the electrical interconnect board of claim 1;
wherein each of the plurality of battery cells is arranged within a corresponding one of the receptacles, such that the battery cells are connected with each other to form a circuit of battery cells.
